(19) United States
(12) Patent Application Publication
(10) Pub. No.: US 2006/0268696 A1
(43) Pub. Date: Nov. 30, 2006

(54) Data packets scrambling module and method

(76) Inventors: Alain Konstantinov, Laval (CA); Kenneth Ormsby, I'lle Bizard (CA)

Correspondence Address: ALEX NICOLAESCU;Ericsson Canada Inc., Patent Department, 8400 Decarie Blvd., Town Mount Royal, QC, H4P 2N2, CA

(21) Appl. No.: 11/231,858

(22) Filed: Sep. 22, 2005

Related U.S. Application Data
(60) Provisional application No. 60/684,229, filed on May 25, 2005.

(51) Int. Cl. H04L 12/26; H04J 3/22; H04L 1/00; H04J 3/16; G01R 31/08; G06F 11/00; H04J 1/16; H04J 3/14; G08C 15/00

(52) U.S. Cl. 370/229; 370/465

(57) ABSTRACT

A method and scrambling module for degrading delay-sensitive traffic quality in a telecommunications network, wherein data packets that meet a pre-defined rule are detected and delayed by inducing a delay. The scrambling module comprises an access list comprising the pre-defined rule(s) for detecting certain data packets, a packet detector configured to detect the data packets that meet the pre-defined rule, and a delay inducer module acting to induce a delay to the data packets. The delay is variable for consecutive data packets and may follow a seesaw-like function, a random function, or any other type of function for consecutive data packets. The data packets are detected based on the rule, which may contain indications for intercepting the data packets based on their origination from a certain application port number, destination to a certain application port number, origination from an address identified in the pre-defined rule, or destination to a certain address.

### PRIORITY STATEMENT UNDER 35 U.S.C S.119 (E) & 37 C.F.R. S.1.78

This non-provisional patent application claims priority based upon the prior U.S provisional patent application entitled “Controlled Degradation of non-MNO VoIP Services”, application No. 60/684,229 filed May 5, 2005 in the name of Alain KONSTANTINOV of Laval, Canada, and Kenneth ORMSBY of Île-Bizard, Canada.

### BACKGROUND OF THE INVENTION

1. Field of the Invention

The present invention relates to the field of delay-sensitive data traffic such as for example Voice-over-Internet-Protocol (VoIP) data traffic and its transport over telecommunications networks.

2. Description of the Related Art

In the last two decades telecommunication networks have evolved from the Public Switched Telephone Networks (PSTN) to the First Generation (1G) of analog signal based cellular networks, further to the digital signal based second-generation (2G) cellular networks, to achieve today end-to-end digital signaling and data transfer using the well known Internet Protocol (IP) in the 3^{rd} Generation (3G) cellular telecommunications networks. In 3G networks, as well as in evolutions thereof, voice and data communications are performed by the exchange of IP data packets. Subscribers are not only allowed to exchange or to receive various kinds of data such as for example music files, images files, video files, application programs, etc., but are also provided voice communication service, which technically involves the sampling and packetizing of the voice sound signal in IP format before being exchanged among subscribers.

The transition from one generation to another of an entire cellular telecommunication network necessitates major investments by mobile network operators. Such major expenses have been justified by significant competition between mobile network operators and by the opportunity to offer subscribers data access mobility.

While mobile network operators have always been in charge of deploying, managing, and upgrading their telecommunications networks with state-of-the-art equipment, the transition of these networks toward IP-based communications has provided the possibility for third-party application providers to take advantage of the openness of the IP-based networks and of their connectivity to the Internet. As a consequence, third-party application providers have recently offered software applications that begin to represent an actual competition for services that were traditionally solely provided by the network operators. One illustrative example is voice communication, which has been, and still is, the most important service offered by traditional telecommunication networks with IP capability, both fixed (e.g. PSTN) and mobile (e.g. cellular telecommunication networks). However, given the possibility to access the IP-based networks of traditional network operators in the last few years, third-party application providers have begun offering voice communications services using the so-called Voice Over IP (VoIP) technology, which offers simple client applications for installation on subscribers terminals (PCs, laptops, PDAs, smartphones, etc), which do not send packetized voice data over traditional channels, but rather allows the packetizing of voice sound signal into data packets which are then sent over the Internet, like any other data packets, and so avoids the normal charges incurred for voice communication. In other words, subscribers that take advantage of a VoIP-enabled terminal have only to pay for data-type connection with their network operator while they are also capable of receiving voice service.

This situation significantly affects the income of traditional network operators. For example, a subscriber of an Internet Service Provider (ISP) may connect to the Internet via a home cable (or DSL) modem provided by the ISP and pay a monthly fee for the data access to the Internet. The subscriber may install a VoIP client application on his laptop terminal, which he uses for carrying on voice communications. The subscriber can then initiate and receive voice communications with other Internet users, cellular users, or fixed telephone users, via his VoIP client application, both in local or long-distance areas, thus circumventing the payment of a regular voice subscription.

Another example may be constituted by a 3G cellular subscriber, who could install on his JAVA-enabled 3G mobile terminal a VoIP client application, which he uses for carrying on voice communications using VoIP. Again, in this example the subscriber is only billed by the mobile network operator for the volume of the exchanged data (including the VoIP traffic), but not for regular voice subscription.

This change creates a problem for traditional network operators since even today, and most probably for a long period of time, traditional voice service billing generates the major part of their revenues. However, because the deployment and the maintaining of the communication networks has required significant investments from the mobile network operators and because the pricing scheme for voice service is proportional to the investments made by these operators, a situation has been created today in the market of voice communications wherein third-party providers of VoIP applications can offer much lower prices for VoIP voice service. Because third-party providers of VoIP did not participate to these major investments, but rather simply developed low-cost software applications for the provision of VoIP service, their offerings in terms of pricing are of no match for traditional network operators. This situation occurs despite the fact that the VoIP service offered by third-party providers makes use of the same telecommunication networks deployed, maintained and operated by traditional network operators.

Major network operators have thus foreseen a risk in losing their voice-based revenues and their replacement with volume-based charging of packetized data voice. This inevitably results in a significant loss of revenues for major network operators. Therefore, in order to protect their revenues, traditional network operators are in need to apply a proper charging rate for VoIP traffic that is at par with traditional voice service offering. Preferably, this should be done both for internal VoIP offering (VoIP service provided by the traditional network operators within their own networks), which is under the control of the traditional network operator, and for third-party VoIP service providers. Thus, there is a need for a solution that can guaranty a fair competition in the market of voice communications in order to protect the investment and business model of network operators.

In order to cope with this issue, which has been intensely debated in the industry and in different technical forums, several possible technical solutions have been investigated. One of these solutions involves the voluntary blocking by traditional network operators of VoIP software applications data traffic. Based on this proposed solution, when a traditional network operator detects illegitimate VoIP data traffic transiting by one of its switching nodes, it may block that data flow. Some proposals teach to analyze the content, i.e. the payload of data packets in order to detect VoIP-type of data, and based on this packet analysis to block the data flow. However, this packet data analysis requires the analysis of the content of each and every packet data to locate voice-like data patterns, which necessitates extensive processing resources.

An issue that is also currently debated along with this proposed solution is the legality of blocking an entire data flow by a network operator. While in both the USA and Canada the government regulation agencies require equal access to PSTN (fixed networks with dedicated circuit-switched lines) infrastructure for long distance service providers, the issue is still unsettled in the case of IP-based telecommunications networks.

Accordingly, there is a need in the industry for a technical solution that restores a fair competition in the area of voice service provision between traditional telecommunication network operators and third-party VoIP application providers. Preferably, such a solution would not completely and plainly block VoIP data traffic, but rather offer an elegant and legal alternative for both traditional networks operators and third-party VoIP application providers. The present invention provides such a solution.

### SUMMARY OF THE INVENTION

In one aspect, the present invention is a method for degrading delay-sensitive data traffic quality in a telecommunications network, the method comprising the steps of:
detecting data packets of the data traffic, wherein the data packets meet a certain pre-defined rule; and
delaying the data packets that met the pre-defined rule by inducing a delay to the data packets.

In another aspect, the present invention is a scrambling module for degrading delay-sensitive data traffic quality in a telecommunications network, the scrambling module comprising:
an access list module comprising at least one pre-defined rule for detecting certain data packets;
a packet detector configured to detect data packets of the data traffic that meet the pre-defined rule; and
a delay inducer module that acts to induce a delay to the data packets that met the pre-defined rule.

### BRIEF DESCRIPTION OF THE DRAWINGS

For a more detailed understanding of the invention, for further objects and advantages thereof, reference can now be made to the following description, taken in conjunction with the accompanying drawings, in which:

FIG. 1 is an exemplary high-level network diagram of a telecommunications network implementing the preferred embodiment of the present invention;

FIG. 2 is an exemplary flowchart diagram of a method according to the preferred embodiment of the present invention;

FIG. 3 is an exemplary high-level structure diagram of a data packet used in conjunction with the preferred embodiment of the present invention; and

FIG. 4 is an exemplary high-level block diagram illustrative of a scrambling module implementing the preferred embodiment of the present invention.

### DETAILED DESCRIPTION OF THE PREFERRED EMBODIMENTS

The innovative teachings of the present invention will be described with particular reference to various exemplary embodiments. However, it should be understood that this class of embodiments provides only a few examples of the many advantageous uses of the innovative teachings of the invention. In general, statements made in the specification of the present application do not necessarily limit any of the various claimed aspects of the present invention. Moreover, some statements may apply to some inventive features but not to others. In the drawings, like or similar elements are designated with identical reference numerals throughout the several views.

The present invention provides a method and telecommunication node implementing a simple yet efficient scrambling mechanism that diminishes the level of service (the quality) of illegitimate delay-sensitive data traffic like VoIP service that transits via a telecommunications network. By illegitimate delay-sensitive data traffic (VoIP, video-over-IP, etc, all of which are hereinafter designated with the appellation VoIP) service, it is meant herein delay-sensitive data traffic that transits through the telecommunication network of a certain network operator, but which is not provided by, or specifically charged for, by that network operator. According to the present invention, when a network operator detects data traffic that could comprise illegitimate VoIP traffic in one of its switching nodes, that data traffic (the data packets that constitute the data traffic) may be delayed by a time period that is preferably variable in nature. Accordingly, output VoIP data packets are jumbled, i.e. transmitted out of sequence with an individual, variable, delay, for example. In this manner, the receiving end of the VoIP communication receives the VoIP data packets not only out-of-sequence, but also with a variable delay, and the VoIP client of the receiving end, despite making use of TCP packet sequence reconstituting capabilities, cannot reconstitute voice signal fast enough for insuring quality live voice communications.

The present invention does not inspect the content (the payload) of the data packets like in other prior art methods for detecting the illegitimate VoIP data traffic, thus significantly reducing the required processing resources. Rather, the present invention functions to induce small delays to all data traffic that matches a certain criteria, such as for example that originates or is destined to a given address, or that originates or is destined to a given application port number. For example, if a given VoIP third party application provider uses the HTTP application port number 80 for issuing VoIP data packets, these packets also contain the indication of the originating or destination port number 80 (this is deduced from the normal TCP/UDP packet data structure). With the present invention, network operators may then monitor incoming data packets in their switching nodes and/or routers, inspect only the headers of the data packets, and apply the mechanism of the present invention to all traffic detected to be originated from, or destined to, such port number. This includes the illegitimate VoIP data traffic but may also include non-VoIP data traffic. However, non-VoIP data packets traffic (e.g. legitimate web traffic, audio or video streaming, etc), even if delayed by the operator's nodes, is re-arranged by the TCP mechanism for re-ordering out-of-sequence data packets at the receiving side, so this non-voice data traffic is not disrupted or deteriorated by the present invention, as long as the induced delay does not exceed a given time period, such as for example 0.5 to 1 second. Legitimate UDP traffic is also not impacted by the mechanism of the present invention, because UDP is conceived to carry signalling that is not sensitive to delay and that may be transmitted in any order. But delay-sensitive communications such as VoIP traffic over TCP/UDP are seriously degraded by the added delay and changing of sequence, while the overall throughput of the switching node is preserved.

The scrambling mechanism proposed hereinabove may be preferably enhanced with a network operator's offering of a high-class subscription service. Subscribers of the high-class service could carry on non-scrambled VoIP communications, thus bypassing the present invention, so that all their data traffic, including the VoIP data traffic of third party application providers is transparently relayed over the operator's network. For example, a user can subscribe to the high-class service offering, and therefore be able to carry on non-scrambled VoIP communications.

The present invention thus represents a technical solution that provides an incentive for users of third-party VoIP applications to subscribe to high-class data transfer service from their network operator. With the receipt of additional revenues from the high-class subscriptions to non-scrambled data traffic, the fair competition between traditional network operators and third party application providers of VoIP is re-established and preserved.

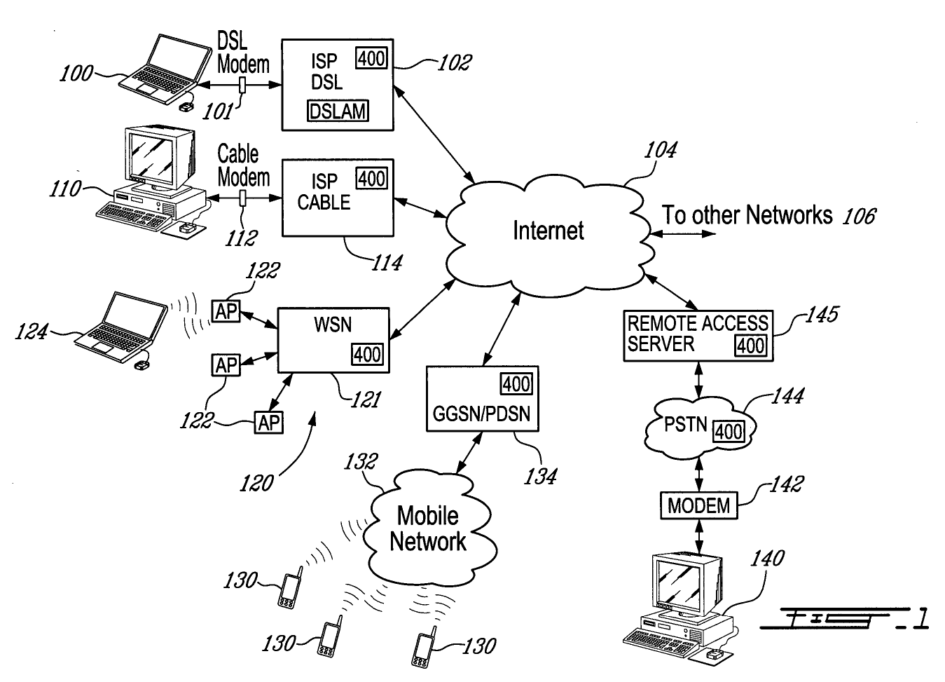

Reference is now made to FIG. 1, which is an exemplary high-level network diagram of telecommunications networks implementing the preferred embodiment of the present invention. Shown in FIG. 1, is an exemplary laptop terminal 100 that connects to the Internet 104 using a home Digital Subscriber Line (DSL) modem 101 linked to a DSL-based Internet Service Provider (ISP) 102, and from there to other networks 106 (e.g. LANs (local Area Networks), WANS (Wide Area networks), etc). Likewise, also shown in FIG. 1, is a Personal Computer (PC) 110 that connects via a cable modem 112 to a cable-type ISP 114 and from there to the Internet 104 and to the other networks 106. The Internet 104 can also be accessed via a Wireless Local Area Network connection (WLAN) 120, which typically has at least one Wireless Service Node (WSN) 121 linked to Access Points (APs) 122, which offer radio hotspots coverage providing wireless connections to WLAN-enabled terminals alike the terminal 124. Mobile clients 130 can also access the Internet 104 and the other networks 106 using mobile networks like the network 132, which typically interface the Internet via a GGSN (Gateway GPRS Serving/Support Node) or PDSN (Packet Data Service Node) switching nodes 134. Finally, a PC-based terminal 140 may also access the Internet and the other networks 106 using a modem 142 and the PSTN 144, which connects to the Internet 104 via a Remote Access Server (RAS) 145, in a manner well known in the art. Each one of the terminals shown in FIG. 1, namely terminals 100, 110, 124, 130, and 140, may have installed therein a VoIP client application that enables voice communications to be carried on by the user of these terminals. Typically, such a VoIP client application enables two-way voice communications with other, remote users, who use similar client applications. A typical VoIP client application running on such a terminal is configured to sample the acoustic voice signal of the user, packetize it into data packets using TCP or UDP protocols and send it over the Internet 104 to the other party involved in the communication. The receiving terminal which runs the same client application is then responsible for depacketizing the data containing the voice signal and for playing the voice signal sound for the receiving user, as well as for performing the same packetizing action in the reverse direction so that full-duplex communications are achieved.

According to the present invention, a network operator of any one of the telecommunications nodes (or networks) 102, 114, 120, 134, and 145 illustrated in FIG. 1, may implemented therein a scrambling module 400 responsible for scrambling data traffic that match a certain criteria or rules, so that the quality of illegitimate VoIP data traffic that transits there through is diminished. The function of the scrambling module 400 is to detect data traffic that matches the certain criteria or rules so that the illegitimate VoIP data traffic is detected, and to apply a delay to the individual data packets of the illegitimate VoIP data traffic, In this manner, these packets are output in a delayed and jumbled manner. The quality of the voice communication at the receiving side of the VoIP communication is therefore degraded to a certain extent.

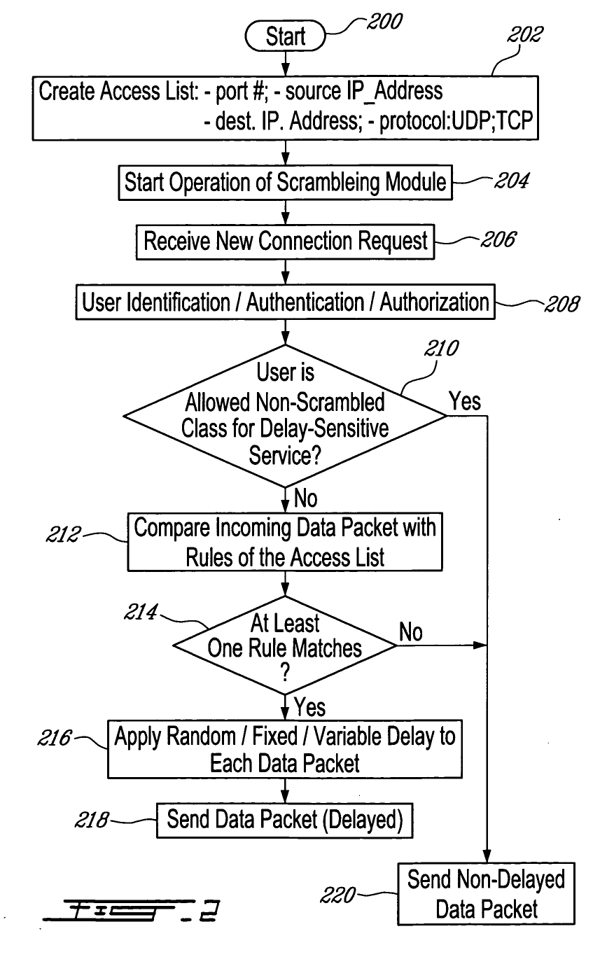

Reference is now made jointly to FIG. 2, which is an exemplary flowchart diagram of a method according to the preferred embodiment of the present invention, and to FIG. 4, which is an exemplary high-level block diagram illustrative of a scrambling module 400 implementing the preferred embodiment of the present invention. The method starts in action 200, and in action 202 an access list 404 is created for specifying which VoIP communications (or any other delay-sensitive communications) should be intercepted and scrambled by the scrambling module 400. Such an access list 404 may contain various rules 406 that may specify indications and/or conditions where delay-sensitive communications should be intercepted and scrambled, such as for example indications of source IP addresses, destination IP addresses of parties whose communications are to be intercepted and scrambled, protocols used for carrying on VoIP communications, port numbers identifiers, MAC addresses, etc. For example, one of the rules 406 for intercepting and scrambling a delay-sensitive communication may be as follows:
Action: intercept and scramble
Source IP address: 148.111.113.11
Port number: 80

As a consequence of the above-mentioned rule, the scrambling module 400 intercepts data packets originating from the mentioned source IP address and which are destined or originated from port number 80 of the sending or of the receiving terminal.

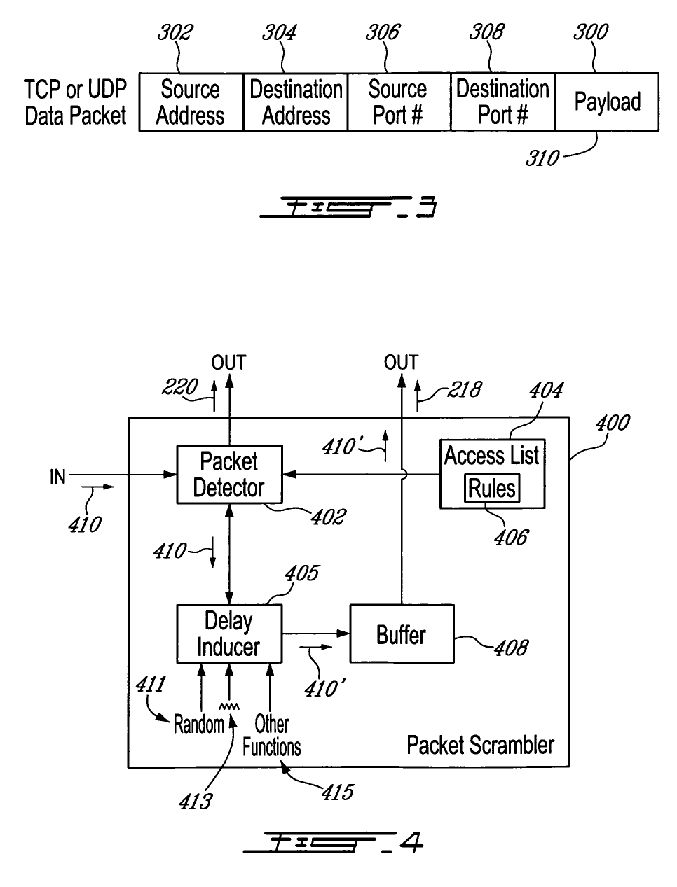

In order to better understand the present invention, reference is now made to FIG. 3, which is a simplified high-level structure diagram of a data packet 300 used in conjunction with the preferred embodiment of the present invention. FIG. 3 shows a typical structure of a TCP/UDP data packet. Such a data packet 300 typically comprises, among other fields and headers, a source IP address header 302, a destination IP address header 304, a source port number header 306 that indicates the application port number that originated the data packet, a destination port number 308 that indicates to each application port number the data packet is destined to, and finally a data payload 310 that comprises the payload of the data packets 300. A full and detailed description of an IP data packet structure is provided in the Request For Comments (RFC) 791, entitled “Internet Protocol—DARPA Internet Program Protocol Specification”, section 3.1, published in September 1981, by Postel, J. (ed.)/USC/Information Sciences Institute, all of which is herein included by reference in its entirety. Likewise, a full and detailed description of a TCP data packet structure is provided in the Request For Comments (RFC) 793, entitled “Internet Protocol—DARPA Internet Program Protocol Specification”, section 3.1, published in September 1981, by Postel, J. (ed.)/USC/Information Sciences Institute, all of which is also herein included by reference in its entirety. Finally, a full and detailed description of a UDP data packet structure is provided in the Request For Comments (RFC) 768, entitled “User Datagram Protocol”, published in August 1980, by Postel, J. (ed.)/USC/Information Sciences Institute, all of which is also herein included by reference in its entirety.

In accordance with the preferred embodiment of the present invention, the scrambling module 400 may detect based on the rules 406 of its access list 404, for example, the source or destination IP addresses 302 and/or 304, and/or the source or destination port numbers 306 and/or 308, alone or in combination, of the incoming data packets 410. Once this detection is effectuated, the module 400 acts to scramble the data packets 410 in a manner that is yet to be described.

With reference being now made back to FIGS. 2 and 4, once the access list 404 is created in action 202, the method continues with the start of the normal operation of the scrambling module, action 204. From this time on, the scrambling module 400 acts to detect data packets of interest based on the rules 406 of the access list 404, for data traffic that transits via the switching node that implements the scrambling module (see FIG. 1, for example). In action 206, the switching node that implements the scrambling module 400 may receive a new connection request for establishing a new VoIP communication, and in action 208 the user that issued the connection request is identified, authenticated, and authorized, in order to determine whether or not the user is allowed to carry on the requested service, i.e. for example a VoIP communications. The action 206 may be optional, so it is not present in all implementations. For example, action 206 may not exist, in which case the user identity may be deduced from the VoIP data packets themselves using the originating IP address and/or an originating MAC (Media Access Control) address, and used in action 210 for identifying, authorizing and authenticating the user. Depending upon the nature of the network, the identification, authentication, and authorization of action 208 may involve accessing a local or remote user register, such as for example a Home Location Register (HLR), a Home Subscriber Service (HSS), or a Authentication, Authorization, and Accounting (AAA) server, etc, and to receive back from the user register an indication of the successful or unsuccessful identification, authentication, or authorization of the user. Based on the information received back from the user register, the scrambling module 400 determines in action 210 if the user is allowed a non-scrambled class of service (e.g. high-class service) for delay sensitive service such as for the requested VoIP communication. If so, the scrambling module does not apply any delay, and the data packets of the VoIP communication are output as they arrive with no induced delay, action 220. Otherwise, if in action 210 it is rather detected that the user is not allowed the higher class of service for delay-sensitive applications such as VoIP communications, or if simply no actions 206-208 are performed at all like it may be the case in some implementations, in action 212 the scrambling module 400 compares incoming data packets 410 of the VoIP communication with the rules 406 of the access list 404 in order to determine if any match is found between the information contained in the data packets 410 and the rules 406. A packet detector 402 of the scrambling module 400 may perform action 212. In action 214, the packet detector 402 determines if there is any match between the information contained in the headers of the incoming data packets 410 of the VoIP communication and the rules 406. If not, the data packets of the VoIP communication are not scrambled, but rather sent with no induced delay as they arrive, action 220. Otherwise, if in action 214 the packet detector 402 determines that the data packets 410 match at least one of the rules 406, the method moves to action 216 where a delay is applied to the data packets 410. For this purpose, the packet detector routes the data packets 410 to a delay inducer module 405 of the scrambling module 400, which may add/assign a delay to each data packets or to a group of data packets of the data packets 410. Various types of delays may be induced/assigned to consecutive data packets, such as for example a random delay 411, a delay following a seesaw function 413 or any another type of function 415. The delayed data packets 410′ may then be transferred into a buffer 408 for the duration of the assigned delay. Once the delay expires, the delayed data packets 410′ are sent to their destination, action 218.

Therefore, with the present invention it becomes possible to jumble data packets of an illegitimate delay-sensitive communication that is carried over a given network. As a consequence, the quality of the delay-sensitive communication is degraded to a certain extent. Such degradation is proportional to the size of the delay that is induced to each data packet of the delay sensitive communication. Preferably, the induced delays are set to range from a minimum delay up to a maximum delay, and the range of the delays is user-configurable. Therefore, even in the exemplary case wherein the delays follow a certain function, e.g. random, seesaw, or other, the function is set to vary within a certain range. For example, in order to only affect the quality of delay-sensitive communications such as for example VoIP and video-over-IP, but not the quality of other communications that could be carried on the same application port number (for example), the delay may preferably range from 0.1 to 1 second.

Based upon the foregoing, it should now be apparent to those of ordinary skills in the art that the present invention provides an advantageous solution, which re-establishes a fair competition between the service provided by a traditional network operator and third-party application providers of delay-sensitive service such as VoIP or video-over-IP. Although the system and method of the present invention have been described in particular reference to certain delay-sensitive communications such as VoIP or video-over-IP, it should be realized upon reference hereto that the innovative teachings contained herein are not necessarily limited thereto and may be implemented advantageously with any applicable delay-sensitive communication. It is believed that the operation and construction of the present invention will be apparent from the foregoing description. While the method and system shown and described have been characterized as being preferred, it will be readily apparent that various changes and modifications could be made therein without departing from the scope of the invention as defined by the claims set forth hereinbelow.

Although several preferred embodiments of the method and system of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for degrading delay-sensitive data traffic quality in a telecommunications network, the method comprising the steps of:
detecting data packets of the data traffic, wherein the data packets meet a certain pre-defined rule; and
delaying the data packets that met the pre-defined rule by inducing a delay to the data packets.

2. The method claimed in claim 1, wherein the delay induced is a delay that is variable for consecutive data packets.

3. The method claimed in claim 2, wherein the delay induced follows a seesaw-like function for consecutive data packets.

4. The method claimed in claim 1, wherein the delay induced is a random delay for consecutive data packets.

5. The method claimed in claim 1, wherein the step of detecting comprises detecting that the data packets originate from a certain application port number identified in the pre-defined rule.

6. The method claimed in claim 1, wherein the step of detecting comprises detecting that the data packets are destined to a certain application port number identified in the pre-defined rule.

7. The method claimed in claim 1, wherein the step of detecting comprises detecting that the data packets originate from an originating address identified in the pre-defined rule.

8. The method claimed in claim 1, wherein the step of detecting comprises detecting that the data packets are destined to a destination address identified in the pre-defined rule.

9. A scrambling module for degrading delay-sensitive data traffic quality in a telecommunications network, the scrambling module comprising:
an access list module comprising at least one pre-defined rule for detecting certain data packets;
a packet detector configured to detect data packets of the data traffic that meet the pre-defined rule; and
a delay inducer module that acts to induce a delay to the data packets that met the pre-defined rule.

10. The scrambling module claimed in claim 9, wherein the delay induced by the delay inducer is a delay that is variable for consecutive data packets.

11. The scrambling module claimed in claim 10, wherein the delay induced by the delay inducer follows a seesaw-like function for consecutive data packets.

12. The scrambling module claimed in claim 9, wherein the delay induced by the delay inducer is a random delay for consecutive data packets.

13. The scrambling module claimed in claim 9, wherein the packet detector detects that the data packets originate from a certain application port number identified in the pre-defined rule.

14. The scrambling module claimed in claim 9, wherein the packet detector detects that the data packets are destined to a certain application port number identified in the pre-defined rule.

15. The scrambling module claimed in claim 9, wherein the packet detector detects that the data packets originate from an originating address identified in the pre-defined rule.

16. The scrambling module claimed in claim 9, wherein the packet detector detects that the data packets are destined to a destination address identified in the pre-defined rule.
